(19) United States
(12) Patent Application Publication
(10) Pub. No.: US 2020/0044013 A1
(43) Pub. Date: Feb. 6, 2020

(54) SELF-ALIGNED FINGER METAL-OXIDE-METAL (FMOM) AND METHOD OF MAKING THE SAME

(71) Applicant: QUALCOMM Incorporated, San Diego, CA (US)

(72) Inventors: Ye LU, San Diego, CA (US); Haitao CHENG, San Diego, CA (US); Chao SONG, San Diego, CA (US)

(21) Appl. No.: 16/053,124

(22) Filed: Aug. 2, 2018

(51) Int. Cl. H01L 49/02; H01L 21/02; H01L 21/283; H01L 21/311

(52) U.S. Cl. CPC H01L 28/87; H01L 21/0226; H01L 21/283; H04B 1/40; H01L 21/02175; H01L 21/31111; H01L 21/02181

(57) ABSTRACT

A capacitor includes a first conductive element having a plurality of first conductive fingers and a second conductive element having a plurality of second conductive fingers. The first conductive fingers are interdigitated with the second conductive fingers. The capacitor further includes a conformally deposited dielectric material that separates the plurality of first conductive fingers from the plurality of second conductive fingers.

### BACKGROUND

### Field

Aspects of the present disclosure relate to semiconductor devices and, more particularly, to capacitors in semiconductor structures.

### Background

In advanced complementary metal-oxide-semiconductor (CMOS) technologies, a finger metal-oxide-metal (FMOM) capacitor is desired for providing a de-coupling capacitor having a high capacitance value within a small device footprint. FMOM capacitors are typically fabricated using a lithography and etch method and, therefore, are restricted by the lithography and etch resolution. In addition, errors as a result of lithography alignment (overlay) may cause capacitance variation of the FMOM capacitors that in turn affect circuit performance and yield. Therefore, there is a desire for a FMOM capacitor that overcomes the minimum pitch resolution of the traditional lithography and etch method and has improved circuit performance and yield.

### SUMMARY

A capacitor may include a first conductive element and a second conductive element. The first conductive element may include a plurality of first conductive fingers, and the second conductive element may include a plurality of second conductive fingers that are interdigitated with the plurality of first conductive fingers. The capacitor may further include a conformally deposited dielectric material that separates the plurality of first conductive fingers from the plurality of second conductive fingers.

A method of fabricating a capacitor may include providing a first conductive element composed of a first conductive material on a substrate. The first conductive element may include a plurality of first conductive fingers. The method may further include conformally depositing a dielectric material on the first conductive element including the plurality of first conductive fingers. The method may further include depositing a second conductive material to form a second conductive element including a plurality of second conductive fingers interdigitated with the plurality of first conductive fingers.

Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a radio frequency (RF) front end (RFFE) module employing passive devices.

FIG. 2 is a schematic diagram of a radio frequency (RF) front end (RFFE) module employing passive devices for a chipset.

FIG. 3 is a top plan view of a conventional FMOM capacitor structure.

FIG. 4A is a cross-sectional view taken generally along the line A-A of the FMOM capacitor structure shown in FIG. 3.

FIG. 4B is a cross-sectional view of a conventional FMOM capacitor structure showing a misalignment between the positive and negative electrodes.

FIG. 5 is a top plan view of a FMOM capacitor structure, according to aspects of the present disclosure.

FIG. 6A is a cross-sectional view taken generally along the line B-B of the FMOM capacitor of FIG. 5, according to aspects of the present disclosure.

FIG. 6B is a cross-sectional view an FMOM capacitor structure illustrating that the positive and negative electrodes may have different widths, according to aspects of the present disclosure.

FIG. 7 is a top plan view of another FMOM capacitor structure, according to aspects of the present disclosure.

FIG. 8 is a cross-sectional view taken generally along the line C-C of the FMOM capacitor of FIG. 7.

FIGS. 9A-9E illustrate a fabrication process for FMOM capacitor structures, according to aspects of the present disclosure.

FIG. 10 is a process flow diagram illustrating a method for fabricating FMOM capacitor structures, according to aspects of the present disclosure.

FIG. 11 is a block diagram showing an exemplary wireless communications system in which a configuration of the present disclosure may be advantageously employed.

FIG. 12 is a block diagram illustrating a design workstation used for circuit, layout, and logic design of a finger metal-oxide-metal (FMOM) capacitor structure according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. The term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Mobile communications devices have become common. The prevalence of these mobile devices is driven in part by the many functions that are now enabled on such devices. Demand for such functions increases processing capability specifications and creates a desire for more powerful batteries. Within the limited space inside the housing of a mobile communications device, batteries compete with the processing circuitry. These and other factors contribute to a continued miniaturization of components within the mobile communications device.

Miniaturization of the components impacts all aspects of the processing circuitry including the transistors and passive elements of the processing circuitry, such as capacitors. One miniaturization technique involves moving some passive elements from the printed circuit board into the integrated circuitry. One technique for moving passive elements into the integrated circuitry involves creating metal-oxide-metal (MOM) capacitors during back-end-of-line (BEOL) integrated circuit fabrication. Each integrated circuit complies with a collection of process parameters for allowing manufacturing of circuits for operating under desired specifications (sometimes called a “process window”). The process window may be unique to a particular integrated circuit or may be duplicated across a product line or have other applications as desired. Nevertheless, the existence of a corresponding process window effectively sets forth the thresholds with which an integrated circuit complies to be suitable for functioning as designed (e.g., an integrated circuit in a mobile communications device).

Many current back-end-of-line MOM capacitors have a two element interdigitated structure. Such capacitors are created using masks and deposition processes. In such processes, a substrate may be provided with masks that are positioned thereon. A deposition technique may generate the two conductive elements of the capacitor. In this regard, the two conductive elements form the positive and negative nodes of the capacitor. Because capacitance is a function of the size of the conductive elements, increased capacitance is achieved through larger positive and negative nodes. Nevertheless, larger nodes increase the footprint of the capacitor, defeating the miniaturization goals. In addition, the larger nodes conflict with the process window and increase local stress significantly.

Advances in lithography have reduced line spacing to the nanometer range in integrated circuit chips. The reduced line spacing increases the available area for capacitance because more lines of charge storage can be placed in the same volume of material. Further, back-end-of-line interconnect structures, as described in one aspect of the present disclosure, allow for an improved capacitor structure.

In advanced complementary metal-oxide-semiconductor (CMOS) technologies, a finger metal-oxide-metal (FMOM) capacitor is used as a de-coupling capacitor, which has a high capacitance value with a small device footprint. Conventional FMOM capacitor structures are fabricated using a lithography and etch method. As a result, these FMOM capacitor structures are restricted by the lithography and etch resolution. In addition, since the conductive elements that form the positive and negative nodes of FMOM capacitor structure are formed separately, the FMOM capacitor structure is susceptible to lithography alignment (overlay) errors that cause capacitance variation in the FMOM capacitor structure that can in turn affect circuit performance and yield. Therefore, there is a desire for a FMOM capacitor structure that overcomes these deficiencies.

Aspects of the present disclosure provide a self-aligned FMOM capacitor structure that overcomes the minimum pitch resolution the traditional lithography and etch method. Forming a FMOM capacitor structure using a conformally deposited high-k dielectric material enables the FMOM finger pitch to be smaller than the minimum pitch resolution the conventional lithography and etch method. Thus, the capacitance density of the self-aligned FMOM capacitor structure would be higher than that of a conventionally formed FMOM capacitor structure having the same device footprint. Since the process is self-aligned, it eliminates any overlay issues and reduces FMOM capacitor variation, thereby improving device and circuit yield. This process also reduces a lithography step and eliminates one mask, providing a significant cost saving.

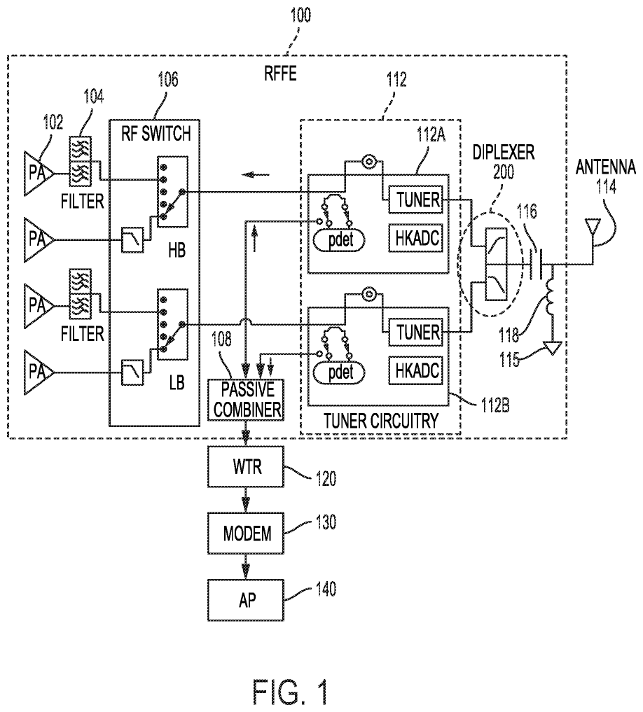

FIG. 1 is a schematic diagram of a radio frequency (RF) front end (RFFE) module 100 employing passive devices including a capacitor 116 (such as finger metal-oxide-metal (FMOM) capacitor structure) that could be integrated with an inductor 118. The RF front end module 100 includes power amplifiers 102, duplexer/filters 104, and a radio frequency (RF) switch module 106. The power amplifiers 102 amplify signals to a certain power level for transmission. The duplexer/filters 104 filter the input/output signals according to a variety of different parameters, including frequency, insertion loss, rejection, or other like parameters. In addition, the RF switch module 106 may select certain portions of the input signals to pass on to the rest of the RF front end module 100.

The radio frequency (RF) front end module 100 also includes tuner circuitry 112 (e.g., first tuner circuitry 112A and second tuner circuitry 112B), the diplexer 200, a capacitor 116, an inductor 118, a ground terminal 115, and an antenna 114. The tuner circuitry 112 (e.g., the first tuner circuitry 112A and the second tuner circuitry 112B) includes components such as a tuner, a portable data entry terminal (PDET), and a house keeping analog to digital converter (HKADC). The tuner circuitry 112 may perform impedance tuning (e.g., a voltage standing wave ratio (VSWR) optimization) for the antenna 114. The RF front end module 100 also includes a passive combiner 108 coupled to a wireless transceiver (WTR) 120. The passive combiner 108 combines the detected power from the first tuner circuitry 112A and the second tuner circuitry 112B. The wireless transceiver 120 processes the information from the passive combiner 108 and provides this information to a modem 130 (e.g., a mobile station modem (MSM)). The modem 130 provides a digital signal to an application processor (AP) 140.

As shown in FIG. 1, the diplexer 200 is between the tuner component of the tuner circuitry 112 and the capacitor 116, the inductor 118, and the antenna 114. The diplexer 200 may be placed between the antenna 114 and the tuner circuitry 112 to provide high system performance from the RF front end module 100 to a chipset including the wireless transceiver 120, the modem 130, and the application processor 140. The diplexer 200 also performs frequency domain multiplexing on both high band frequencies and low band frequencies. After the diplexer 200 performs its frequency multiplexing functions on the input signals, the output of the diplexer 200 is fed to an optional LC (inductor/capacitor) network including the capacitor 116 and the inductor 118. The LC network may provide extra impedance matching components for the antenna 114, when desired. Then, a signal with the particular frequency is transmitted or received by the antenna 114. Although a single capacitor and inductor are shown, multiple components are also contemplated.

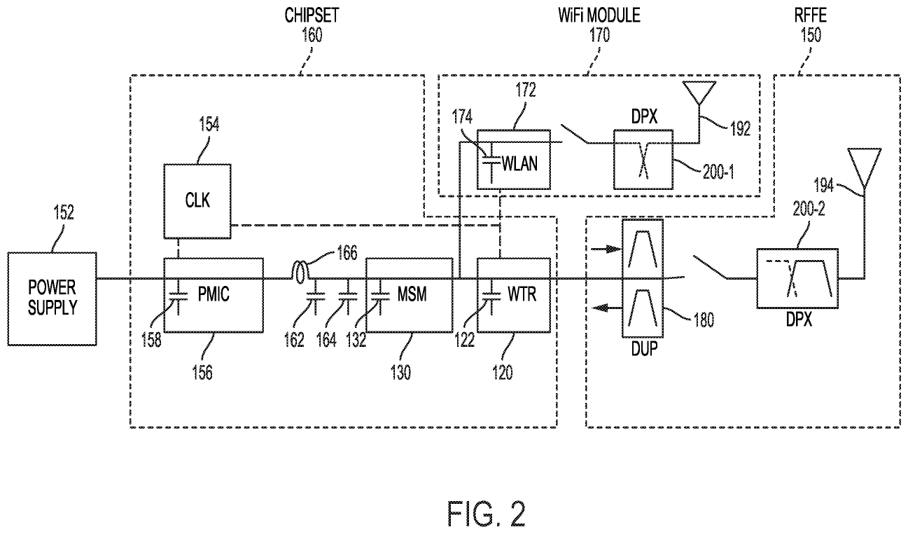

FIG. 2 is a schematic diagram of a wireless local area network (WLAN) (e.g., WiFi) module 170 including a first diplexer 200-1 and an RF front end (RFFE) module 150 including a second diplexer 200-2 for a chipset 160, including a finger metal-oxide-metal (FMOM) capacitor structure. The WiFi module 170 includes the first diplexer 200-1 communicably coupling an antenna 192 to a wireless local area network module (e.g., WLAN module 172). The RF front end module 150 includes the second diplexer 200-2 communicably coupling an antenna 194 to the wireless transceiver (WTR) 120 through a duplexer 180. The wireless transceiver 120 and the WLAN module 172 of the WiFi module 170 are coupled to a modem (MSM, e.g., baseband modem) 130 that is powered by a power supply 152 through a power management integrated circuit (PMIC) 156. The chipset 160 also includes capacitors 162 and 164, as well as an inductor(s) 166 to provide signal integrity.

The PMIC 156, the modem 130, the wireless transceiver 120, and the WLAN module 172 each include capacitors (e.g., 158, 132, 122, and 174) and operate according to a clock 154. In addition, the inductor 166 couples the modem 130 to the

PMIC 156. The geometry and arrangement of the various capacitors and inductor in the chipset 160 may consume substantial chip area.

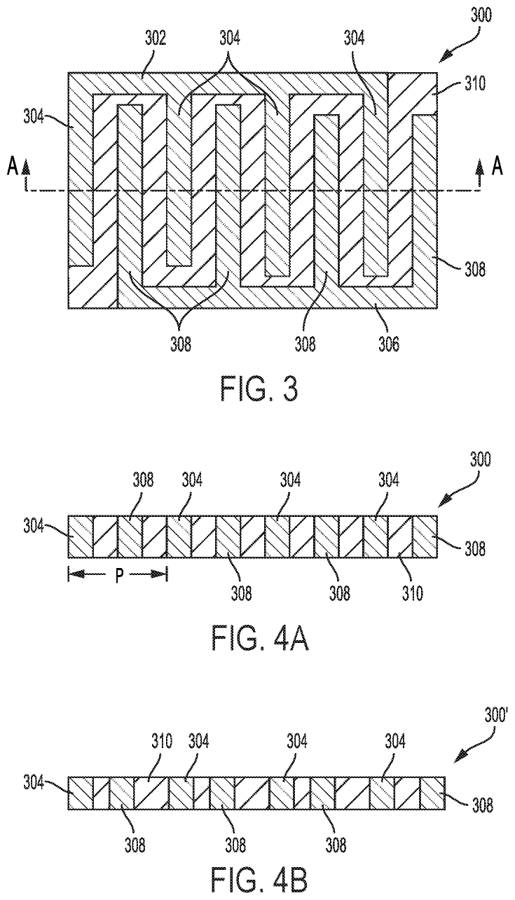

FIG. 3 is a top plan view of a conventional finger metal-oxide-metal (FMOM) capacitor structure 300. The convention FMOM capacitor structure 300 includes a first conductive element 302 having a plurality of first conductive fingers 304. The first conductive element 302 may form a positive node of the FMOM capacitor structure 300. The FMOM capacitor structure 300 further includes a second conductive element 306 having a plurality of second conductive fingers 308. The second conductive element 306 may form a negative node of the FMOM capacitor structure 300. The second conductive fingers 308 are interdigitated with the first conductive fingers 306. The FMOM capacitor structure 310 further includes a dielectric material 310 provided between the alternating first conductive fingers 304 and second conductive fingers 308.

FIG. 4A is a cross-sectional view taken along the line A-A of FIG. 3 and better illustrates the interdigitated first and second conductive fingers 304 and 308, respectively, which are separated by the dielectric material 310. The conventional FMOM capacitor structure 300 has a finger pitch P that is limited by a minimum metal line pitch that can be patterned by lithography in a specific technology. For example, the finger pitch P may be as small as 48 nm, which includes a 24 nm wide metal line and a 24 nm wide dielectric spacer. Although FIG. 4A shows a single layer, the FMOM capacitor structure 300 may also be provided with two or more layers.

The first conductive element 302 and the second conductive element 306 of the FMOM capacitor structure 300 are formed using a conventional lithography and etch process that first includes deposition of a layer of dielectric material. Using a first mask, the first conductive element 302 may then be deposited by lithography, etching and deposition of a conductive material for the first conductive element 302. Typical conductive materials may include copper, cobalt or ruthenium. A second mask is then used to litho, etch and deposit the conductive material for the second conductive element 306. When the second mask is properly aligned, the spacing between the first conductive fingers 304 of the first conductive element 302 and the second conductive fingers 308 of the second conductive element 306 is uniform as shown in FIG. 4A.

The conventional lithography and etch process for FMOM capacitor structures, however, is susceptible to alignment (overlay) errors. FIG. 4B provides a cross-sectional view of a FMOM capacitor structure 300′ that has misalignment issues. The width of the dielectric material 310 between the first conductive fingers 304 and the second conductive fingers 308 is not uniform, since the second conductive fingers 308 have been shifted to the left due to a mask overlay error. As a result, the FMOM capacitor structure 300′ will suffer from performance issues.

Aspects of the present disclosure provide a self-aligned FMOM capacitor structure. Since the process used to form the FMOM capacitor structure is self-aligned, overlay errors are eliminated. Another advantage of this self-aligned process includes reducing the FMOM capacitor finger pitch to be smaller than the minimum pitch restriction of the conventional litho-etch method, which results in a FMOM capacitor structure that has a higher capacitance density for the same footprint. The self-aligned process also reduces FMOM capacitance variation and improves device and circuit yield. The process also reduces a lithography step and eliminates one mask, providing a cost saving of approximately 50% of FMOM fabrication and 3% of the total chip cost.

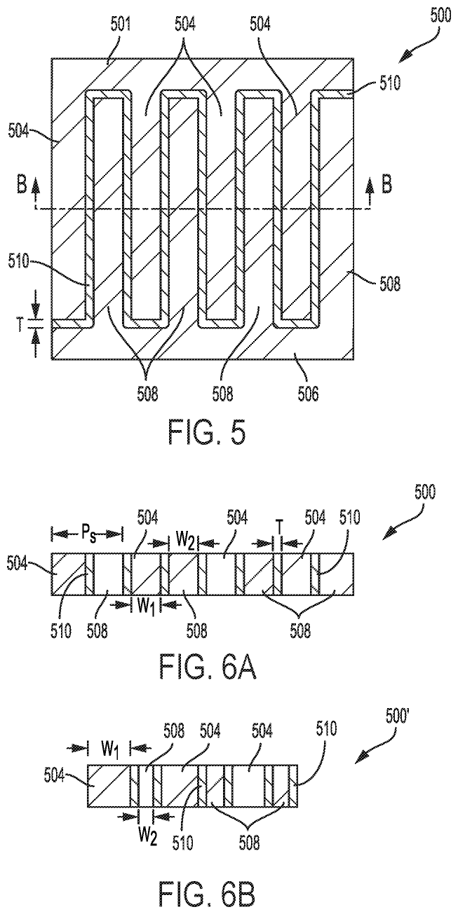

FIGS. 5 and 6B provide top plan and cross-sectional views of a finger metal-oxide-metal (FMOM) capacitor structure 500, according to aspects of the present disclosure. The FMOM capacitor structure 500 may include a first conductive element 502 having a plurality of first conductive fingers 504. The first conductive element 502 may form a positive node of the FMOM capacitor. The FMOM capacitor structure 500 may further include a second conductive element 506 having a plurality of second conductive fingers 508. The second conductive element 306 may form a negative node of the FMOM capacitor. The second conductive fingers 508 are interdigitated with the first conductive fingers 504 to provide capacitive coupling between the alternating conductive fingers 504, 508. The FMOM capacitor structure 500 further includes a dielectric material 510 provided between the alternating first conductive fingers 504 and second conductive fingers 508. Although the FMOM capacitor structure 500 is shown as a single layer FMOM capacitor, the FMOM capacitor structure 500 may also be provided with multiple layers.

The dielectric material 510 is preferably a high-k dielectric material. Example high-k dielectric materials include hafnium oxide and zinc oxide. Regular dielectric materials, such as silicon nitride and aluminum oxide, may also be used in lieu of a high-k dielectric material.

The dielectric material 510 is conformally deposited (e.g., chemical vapor deposition (CVD) or any other process which covers the sidewalls) after the formation of the first conductive element 502 and is then used to align and form the second conductive element 506. Because it is conformally deposited, the dielectric material 510 has a consistent thickness T to provide uniform spacing between the interdigitated first and second conductive fingers 504 and 508, respectively. For example, the thickness T of the dielectric material 510 may be in the range of 1 nm to 30 nm. As a result, the FMOM capacitor 500 may have a reduced finger pitch that is smaller than the minimum pitch resolution of the conventional litho-etch method. By way of example, the FMOM capacitor structure 500 may have a finger pitch Ps of 30 nm, which may include a 24 nm wide metal line and a 6 nm wide dielectric spacer.

Because the conformally deposited dielectric material 510 is used to self-align the second conductive element 506 of the FMOM capacitor structure 500, a finger width W₁ of first conductive element 502 is equal to a finger width W2 of the second conductive element 506, as shown in FIG. 6A. Alternatively, the finger width W₁ of the first conductive element 502 may be different than the finger width W2 of the second conductive element 506. FIG. 6B illustrates an alternative FMOM capacitor structure 500′, in which the finger width W2 of the second conductive element 506 is smaller than the finger width W₁ of the second conductive element 502, and the dielectric material 510 has a uniform thickness.

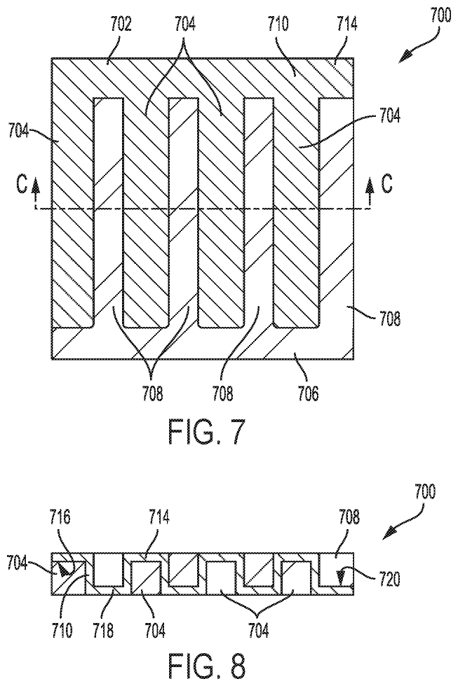

FIGS. 7 and 8 provide top plan and cross-sectional views of another FMOM capacitor structure 700, according to aspects of the present disclosure. The FMOM capacitor structure 700 is similar to the FMOM capacitor structure 500 shown in FIGS. 5 and 6A, except that portions of the dielectric material 510 are not removed from the FMOM capacitor during the fabrication process. The FMOM capacitor 700 includes a first conductive element 702 having a plurality of first conductive fingers 704. The first conductive element 702 may form a positive node of the FMOM capacitor. The FMOM capacitor structure 700 may further include a second conductive element 706 having a plurality of second conductive fingers 708. The second conductive element 706 may form a negative node of the FMOM capacitor. The second conductive fingers 708 are interdigitated with the first conductive fingers 704 to provide capacitive coupling between the alternating conductive fingers 704, 708. The FMOM capacitor structure 700 further includes a dielectric material 710 provided between the alternating first conductive fingers 704 and second conductive fingers 708. The dielectric material 710 further includes a top layer 714 that is provided on a top surface 716 of the first conductive element 704 as well as a bottom layer 817 that is provided beneath a bottom surface 720 of the second conductive element 706.

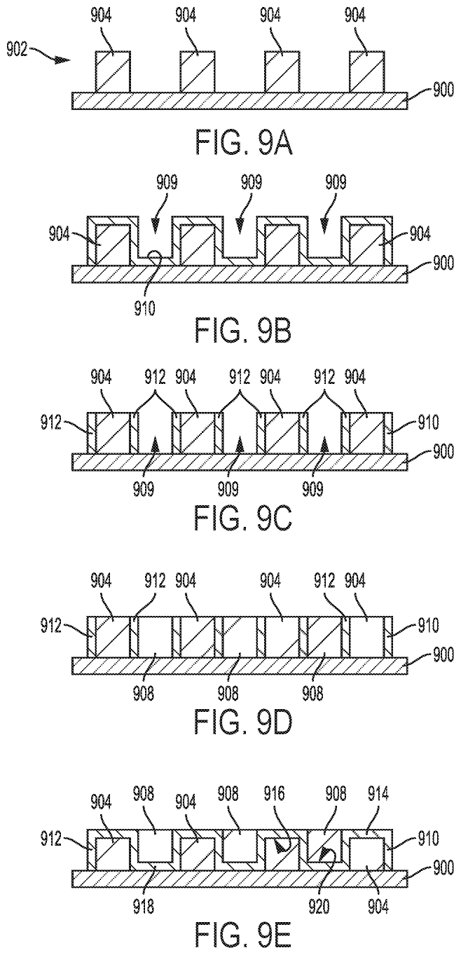

FIGS. 9A-9E illustrate fabrication processes for FMOM capacitor structures 500, 500′ and 700, according to aspects of the present disclosure. As illustrated in FIG. 9A, using a lithography and etch process, a first conductive element 902 is formed on a substrate 900. The first conductive element 902 includes a plurality of first conductive fingers 904.

As illustrated in FIG. 9B, a dielectric material 910 is conformally deposited on the first conductive element 902 to a desired thickness. For example, the dielectric material 910 may be a high-k dielectric, such as hafnium oxide or zinc oxide, with a thickness in the range of 1 nm to 30 nm to provide the desired capacitance. The conformally deposited dielectric material 910 forms self-aligned openings 909 between the first conductive fingers 904.

To form the FMOM capacitor structures 500 and 500′ shown in FIGS. 5, 6A and 6B, the dielectric material 910 is then isotropically etched to remove it from horizontal surfaces on the substrate 900, as shown in FIG. 9C. The isotropic etch may be a reactive-ion etch. Vertical sidewalls 912 of the dielectric material 910 abut the first conductive fingers 904, and the dielectric material 910 is removed from the bottom of the openings 909.

As illustrated in FIG. 9D, a conductive material for the second conductive element 906 including the plurality of second conductive fingers 908 is deposited in the openings 909. The conductive material is then planarized to complete the FMOM capacitor structure of FIGS. 5, 6A and 6B.

To form the FMOM capacitor structure 700 of FIGS. 7 and 8, after conformally depositing the dielectric material in FIG. 9B, the conductive material for the second conductive element 906 including the plurality of second conductive fingers 908 may be immediately deposited in the openings 909, without removal of any dielectric material from the FMOM capacitor. Thus, a top layer 914 of the dielectric material 910 covers the top surface 916 of the first conductive element 902, and a bottom layer 918 of the dielectric material 910 remains beneath a bottom surface 920 of the second conductive element 906, as shown in FIG. 9E.

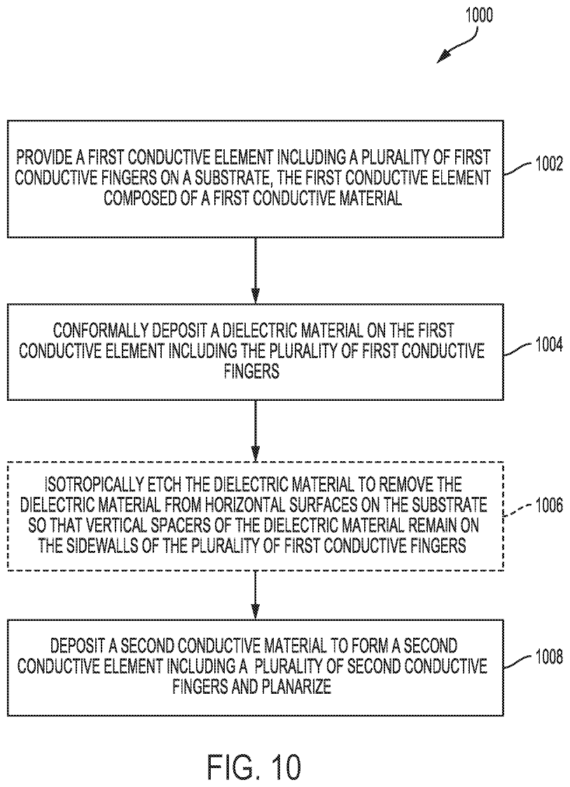

FIG. 10 is a process flow diagram illustrating a method of fabricating a capacitor 1000 according to aspects of the present disclosure. At block 1002, a first conductive element including a plurality of first conductive fingers is provided on a substrate. The first conductive element is composed of a first conductive material. For example, the first conductive element 902 having the plurality of first conductive fingers 904 is provided on the substrate 900, as shown in FIG. 9A.

At block 1004, a dielectric material is conformally deposited on the first conductive element including the plurality of first conductive fingers. For example, the first dielectric material 910 is deposited on the plurality of first conductive fingers 904, as shown in FIG. 9B. The dielectric material 910 may be a high-k dielectric material, such as hafnium oxide or zinc oxide, or a regular dielectric material, such as silicon nitride or aluminum oxide. As discussed earlier, the thickness of the dielectric material 910 may be in the range of 1 nm to 30 nm. The conformally deposited dielectric material 910 provides self-aligned openings 909 between the plurality of first conductive fingers 904, in which to deposit a conductive material for the second conductive element of the FMOM capacitor.

At block 1006, the dielectric material may be isotropically etched to remove it from horizontal surface on the substrate, such that vertical spacers of dielectric material remain on the sidewalls of the plurality of first conductive fingers. For example, as shown in FIG. 9C, the dielectric material 910 has been etched to remove it from the top surface of the plurality of first conductive fingers 904 and from the bottom of the openings 909. The isotropic etch may be a reactive-ion etch. Block 1006 is an optional step that may be used to form the FMOM capacitor structures 500 and 500′ of FIGS. 5, 6A and 6B.

At block 1008, a second conductive material is deposited to form a second conductive element including a plurality of second conductive fingers and then planarized. For example, if the dielectric material 910 has been isotropically etched at block 1006, then there is no dielectric material either on top of the first conductive fingers 904 or beneath the second conductive fingers 908, as shown in FIG. 9D. Alternatively, if the dielectric material has not been etched at block 1006, then the second conductive material may be deposited directly into the dielectric-lined openings 909, and a top layer 914 of dielectric material will cover the first conductive fingers 904 and a bottom layer 918 of dielectric material will be beneath the second conductive fingers 908, as shown in FIG. 9E and resulting in the FMOM capacitor structure 700 of FIGS. 7 and 8.

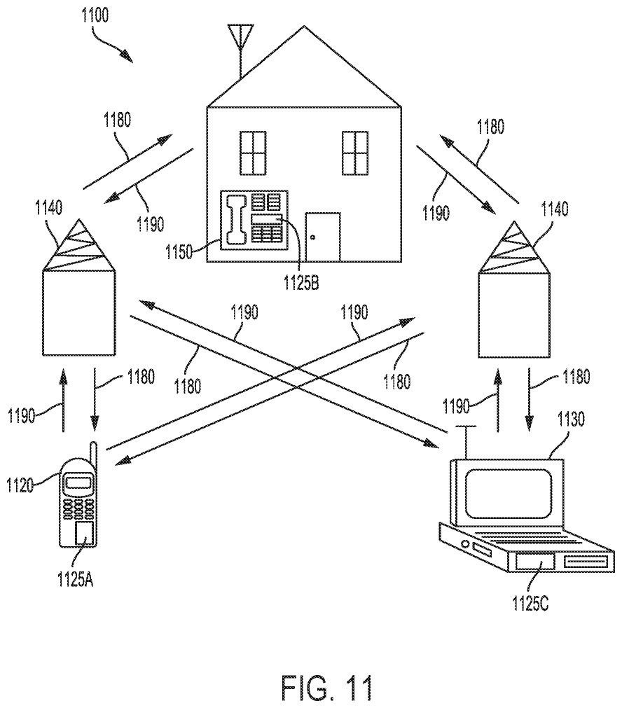

FIG. 11 is a block diagram showing an exemplary wireless communications system 1100 in which an aspect of the present disclosure may be advantageously employed. For purposes of illustration, FIG. 7 shows three remote units 1120, 1130, and 1150 and two base stations 1140. It will be recognized that wireless communications systems may have many more remote units and base stations. Remote units 1120, 1130, and 1150 include IC devices 1125A, 1125C, and 1125B that include the disclosed capacitor. It will be recognized that other devices may also include the disclosed capacitor, such as the base stations, switching devices, and network equipment. FIG. 11 shows forward link signals 1180 from the base station 1140 to the remote units 1120, 1130, and 1150 and reverse link signals 1190 from the remote units 1120, 1130, and 1150 to base stations 1140.

In FIG. 11, remote unit 1120 is shown as a mobile telephone, remote unit 1130 is shown as a portable computer, and remote unit 1150 is shown as a fixed location remote unit in a wireless local loop system. For example, the remote units may be a mobile phone, a hand-held personal communications systems (PCS) unit, a portable data unit such as a personal digital assistant (PDA), a GPS enabled device, a navigation device, a set top box, a music player, a video player, an entertainment unit, a fixed location data unit such as meter reading equipment, or other devices that store or retrieve data or computer instructions, or combinations thereof. Although FIG. 11 illustrates remote units according to the aspects of the present disclosure, the present disclosure is not limited to these exemplary illustrated units. Aspects of the present disclosure may be suitably employed in many devices, which include the disclosed capacitor.

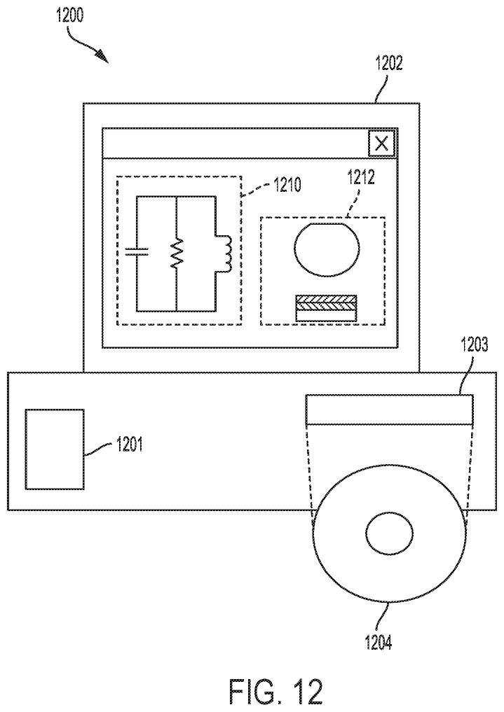

FIG. 12 is a block diagram illustrating a design workstation used for circuit, layout, and logic design of a semiconductor component, such as the capacitor disclosed above. A design workstation 1200 includes a hard disk 1201 containing operating system software, support files, and design software such as Cadence or OrCAD. The design workstation 1200 also includes a display 1202 to facilitate design of a circuit 1210 or a semiconductor component 1212 such as a capacitor. A storage medium 1204 is provided for tangibly storing the design of the circuit 1210 or the semiconductor component 1212. The design of the circuit 1210 or the semiconductor component 1212 may be stored on the storage medium 1204 in a file format such as GDSII or GERBER. The storage medium 1204 may be a CD-ROM, DVD, hard disk, flash memory, or other appropriate device. Furthermore, the design workstation 1200 includes a drive apparatus 803 for accepting input from or writing output to the storage medium 1204.

Data recorded on the storage medium 1204 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1204 facilitates the design of the circuit 1210 or the semiconductor component 1212 by decreasing the number of processes for designing semiconductor wafers.

Although the present disclosure and its advantages have been described in detail, it should be understood that various changes, substitutions, and alterations can be made herein without departing from the technology of the present disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the present disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this present disclosure that are known or later come to be known to those of ordinary skill in the art are expressly incorporated herein by reference and are intended to be encompassed by the claims. Moreover, nothing disclosed herein is intended to be dedicated to the public regardless of whether such present disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “a step for.”

1. A capacitor, comprising:
a first conductive element including a plurality of first conductive fingers;
a second conductive element including a plurality of second conductive fingers, the plurality of second conductive fingers interdigitated with the plurality of first conductive fingers; and
a conformally deposited dielectric material separating the plurality of first conductive fingers from the plurality of second conductive fingers, wherein each of the plurality of first conductive fingers has a first finger width, and each of the plurality of second conductive figures has a second finger width, the first finger width is different from the second finger width.

2. The capacitor of claim 1, wherein the dielectric material has a thickness in the range of 1 nm to 30 nm.

3. The capacitor of claim 1, wherein the dielectric material is a high-k dielectric material.

4. The capacitor of claim 3, wherein the dielectric material is selected from the group consisting of hafnium oxide and zinc oxide.

5. (canceled)

6. The capacitor of claim 1, wherein the conformally deposited dielectric material is also disposed on a top surface of the first conductive element including the plurality of first conductive fingers and beneath a bottom surface of the second conductive element including the plurality of second conductive fingers.

7. The capacitor of claim 6, wherein the dielectric material is a high-k dielectric material.

8. The capacitor of claim 1, integrated into at least one of a music player, a video player, an entertainment unit, a navigation device, a communications device, a personal digital assistant (PDA), a fixed location data unit, a mobile phone, and a portable computer.

9. A method of fabricating a capacitor, comprising:
providing a first conductive element including a plurality of first conductive fingers on a substrate, the first conductive element composed of a first conductive material;
conformally depositing a dielectric material on the first conductive element including the plurality of first conductive fingers; and
depositing a second conductive material to form a second conductive element, the second conductive element including a plurality of second conductive fingers interdigitated with the plurality of first conductive fingers, wherein each of the plurality of first conductive fingers has a first finger width, and each of the plurality of second conductive figures has a second finger width, the first finger width is different from the second finger width.

10. The method of claim 9, wherein conformally depositing the dielectric material includes depositing a high-k dielectric material.

11. The method of claim 10, wherein the high-k dielectric material is selected from the group consisting of hafnium oxide and zinc oxide.

12. The method of claim 9, wherein conformally depositing the dielectric material includes depositing a layer having a thickness in the range of 1 nm to 30 nm.

13. (canceled)

14. The method of claim 9, wherein conformally depositing the dielectric material on first conductive element provides a layer of the dielectric material on a top surface of the first conductive element and a layer of the dielectric material beneath a bottom surface of the second conductive element.

15. The method of claim 9, further comprising isotropically etching the dielectric material to remove the dielectric material from horizontal surfaces on the substrate, wherein vertical spacers of the dielectric material remain on sidewalls of the plurality of first conductive fingers.

16. The method of claim 9, wherein the first conductive material and the second conductive material are the same.

17. The method of claim 9, further comprising integrating the capacitor into at least one of a music player, a video player, an entertainment unit, a navigation device, a communications device, a personal digital assistant (PDA), a fixed location data unit, a mobile phone, and a portable computer.
